(19) United States
(12) Patent Application Publication
(10) Pub. No.: US 2021/0295008 A1
(43) Pub. Date: Sep. 23, 2021

(54) DISPLAY DEVICE CAPABLE OF FINGERPRINT RECOGNITION

(71) Applicant: HiDeep Inc., Seongnam-si Gyeonggi-do (KR)

(72) Inventor: Nam Seok LEE, Seongnam-si Gyeonggi-do (KR)

(21) Appl. No.: 17/264,011

(22) PCT Filed: Aug. 30, 2019
(86) PCT No.: PCT/KR2019/011125

§ 371 Date: Jan. 28, 2021

(30) Foreign Application Priority Data
Aug. 31, 2018 (KR) 10-2018-0103235

(51) Int. Cl. G06K 9/00; G02B 5/30; H01L 27/32; H01L 51/52

(52) U.S. Cl. CPC G06K 9/0004; H01L 51/5293; H01L 27/3227; G02B 5/3025

(57) ABSTRACT

The present invention relates to a display device, and more particularly, to a display device capable of recognizing a fingerprint and enhancing a contrast ratio of a fingerprint pattern. The present invention may include: a cover layer; a linear polarization layer; a phase delay substrate; a plurality of pixels emitting predetermined light; a reflective surface disposed between the phase delay substrate and the plurality of pixels; a photo sensor having a plurality of photo sensor pixels, and receiving an optical signal from a fingerprint which is in contact with or is close to the cover layer and an internal optical noise signal from the reflective surface; and a circular polarizer including a first circular polarization unit passing right-handed circularly polarized light and blocking left-handed circularly polarized light and a second circular polarization unit blocking the right-handed circularly polarized light and passing the left-handed circularly polarized light.

### CROSS-REFERENCE TO RELATED PATENT APPLICATIONS

The present application is a U.S. national stage application under 35 U.S.C. § 371 of PCT Application No. PCT/KR2019/011125, filed Aug. 30, 2019, which claims priority to Korean Patent Application No. 10-2018-0103235, filed Aug. 31, 2018. The disclosures of the aforementioned priority applications are incorporated herein by reference in their entireties.

### TECHNICAL FIELD

The present invention relates to a display device, and more particularly, to a display device which is capable of recognizing a fingerprint and can enhance a contrast ratio of a fingerprint pattern.

### BACKGROUND ART

Display devices using organic light emitting diodes (OLEDs) are widely studied and used.

The organic light emitting diode (hereinafter referred to as OLED) is a self-luminous device, and because the OLED does not require a backlight used in a liquid crystal display device that is a non-light-emitting device, the OLED can be lightweight and thin. In addition, a viewing angle and a contrast ratio of the OLED are superior to those of a liquid crystal display (LCD), and the OLED is advantageous in terms of power consumption, can be driven with DC low voltage, is fast in response speed, and has internal components which are solid, so that the OLED is resistant to external shocks and is wide in used temperature range. In particular, the OLED display devices have the advantage of being able to significantly reduce production costs more than conventional liquid crystal display devices because a manufacturing process is simple.

The OLED display devices with such characteristics are largely divided into a passive matrix type and an active matrix type, and in the passive matrix type, the device is configured in a matrix type while signal lines cross each other, whereas in the active matrix type, a thin film transistor which is a switching device that turns on/off pixels is positioned for each pixel.

Among the conventional OLED display devices, there is an OLED display device capable of recognizing a fingerprint. The conventional OLED display device capable of recognizing the fingerprint has a problem in that the contrast ratio for the detected fingerprint pattern is low. When the contrast ratio of the fingerprint pattern is low, comparing an accurate fingerprint pattern is difficult, and as a result, a study to increase the contrast is required.

### DISCLOSURE

### Technical Problem

An object of the present invention is to provide a display device capable of recognizing a fingerprint, which may enhance a contrast ratio for a fingerprint pattern.

Further, an object of the present invention is to provide a display device capable of recognizing a fingerprint, which may reduce an internal optical noise signal input into a photo sensor.

### Technical Solution

A display device capable of recognizing a fingerprint according to an embodiment of the present invention includes: a cover layer; a linear polarization layer disposed below the cover layer; a phase delay substrate disposed below the linear polarization layer; a plurality of pixels disposed below the phase delay substrate and emitting predetermined light; a reflective surface disposed between the phase delay substrate and the plurality of pixels; a photo sensor disposed below the reflective surface, having a plurality of photo sensor pixels, and receiving an optical signal from a fingerprint which is in contact with or is close to the cover layer and an internal optical noise signal from the reflective surface; and a circular polarizer disposed between the reflective surface and the photo sensor, and including a first circular polarization unit passing right-handed circularly polarized light and blocking left-handed circularly polarized light and a second circular polarization unit blocking the right-handed circularly polarized light and passing the left-handed circularly polarized light.

Here, there may be a plurality of first circular polarization units and a plurality of second circular polarization units, and the plurality of first circular polarization units and the plurality of second circular polarization units may correspond to the plurality of photo sensor pixels one to one, and the plurality of first circular polarization units and the plurality of second circular polarization units may be alternately disposed.

Here, the phase delay substrate may convert the light emitted from each pixel into the right-handed circularly polarized light, and the first circular polarization unit may pass the right-handed circularly polarized light of the optical signal and the internal optical noise signal and block the left-handed circularly polarized light of the internal optical noise signal, and the second circular polarization unit may block the right-handed circularly polarized light of the optical signal and the internal optical noise signal and pass the left-handed circularly polarized light of the internal optical noise signal.

Here, the phase delay substrate may convert the light emitted from each pixel into the left-handed circularly polarized light, and the first circular polarization unit may pass the right-handed circularly polarized light of the internal optical noise signal and block the left-handed circularly polarized light of the optical signal and the internal optical noise signal, and the second circular polarization unit may block the right-handed circularly polarized light of the internal optical noise signal and pass the left-handed circularly polarized light of the optical signal and the internal optical noise signal.

Here, there may be a plurality of first circular polarization units and a plurality of second circular polarization units, and the number of plurality of first circular polarization units may be different from the number of plurality of second circular polarization units.

Here, two or more remaining polarization units may be disposed adjacent to any one polarization unit of the first circular polarization unit and the second circular polarization unit.

Here, a plurality of remaining polarization units may be radially disposed adjacent to any one polarization unit of the first circular polarization unit and the second circular polarization unit.

A display device capable of recognizing a fingerprint according to another embodiment of the present invention includes: a cover layer; a linear polarization layer disposed below the cover layer; a phase delay substrate disposed below the linear polarization layer; a plurality of pixels disposed below the phase delay substrate and emitting predetermined light; a reflective surface disposed between the phase delay substrate and the plurality of pixels; a photo sensor disposed below the reflective surface, having a plurality of photo sensor pixels, and receiving an optical signal from a fingerprint which is in contact with or is close to the cover layer and an internal optical noise signal from the reflective surface; and a circular polarizer disposed between the reflective surface and the photo sensor, and including a circular polarization unit passing any one of right-handed circularly polarized light and left-handed circularly polarized light and blocks the other.

Here, the phase delay substrate may convert the light emitted from each pixel into the right-handed circularly polarized light, and the circular polarizer may pass the right-handed circularly polarized light and block left-handed circularly polarized light.

Here, the phase delay substrate may convert the light emitted from each pixel into the left-handed circularly polarized light, and the circular polarizer may pass the left-handed circularly polarized light and block right-handed circularly polarized light.

Here, the circular polarization layer may be a sheet type, and the circular polarization layer may be attached to a backside of a display panel including the cover layer, the linear polarization layer, the phase delay substrate, the reflective surface, and the plurality of pixels or the photo sensor.

Here, the display device capable of recognizing a fingerprint may further include a control unit detecting a fingerprint pattern of the fingerprint based on a detection signal output from each photo sensor pixel of the photo sensor.

### Advantageous Effects

According to the present invention, when a display device capable of recognizing a fingerprint is used, a contrast ratio for a fingerprint pattern can be enhanced. Accordingly, it is possible to acquire an accurate fingerprint pattern.

Further, it is possible to reduce an internal optical noise signal included in optical signals input into a photo sensor.

### DESCRIPTION OF DRAWINGS

FIG. 1 is a conceptual configuration diagram of a display device capable of recognizing a fingerprint.

FIG. 2 is a conceptual diagram for describing a display device capable of recognizing a fingerprint according to an embodiment of the present invention.

FIGS. 3(a) and 3(b) are perspective views illustrating a part of a modified example of a circular polarizer 100 illustrated in FIG. 2.

FIGS. 4(a) to 4(e) are diagrams for describing a method for manufacturing a circular polarizer 100 illustrated in FIG. 2.

FIG. 5 is a conceptual diagram for describing a display device capable of recognizing a fingerprint according to another embodiment of the present invention.

### MODE FOR INVENTION

The present invention will be described in detail with reference to the accompanying drawings illustrating specific embodiments in which the present invention may be carried out. With respect to the specific embodiments shown in the accompanying drawings, it will be described in detail enough for those skilled in the art to carry out the present invention. Embodiments other than the specific embodiment are different from each other, but need not be mutually exclusive. In addition, it should be understood that the detailed description below is not intended to be taken in a limiting sense.

Detailed descriptions of the specific embodiments illustrated in the accompanying drawings will be read in connection with the accompanying drawings, and the drawings are considered to be part of the description of the entire invention. References to direction or directivity are for convenience of description only, and are not intended to limit the scope of the present invention in any way.

Specifically, terms indicating positions such as “down, up, horizontal, vertical, upper, lower, upward, downward, upper, lower”, or derivatives thereof (for example, “horizontal, downward, upward”, etc.) should be understood with reference to both the described drawings and related descriptions. In particular, since the relative words are for convenience of description only, it is not required that the apparatus of the present invention be configured or operated in a specific direction.

In addition, the thickness and size of each component in the accompanying drawings are exaggerated, omitted, or schematically illustrated for convenience and clarity of description. That is, the size of each component does not entirely reflect the actual size.

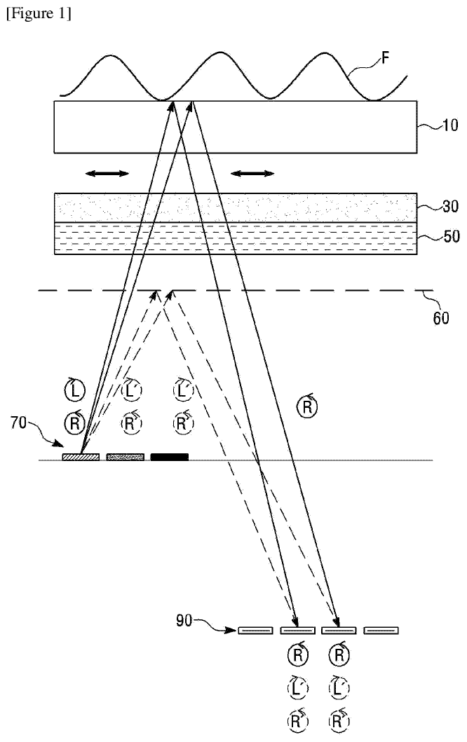

FIG. 1 is a conceptual configuration diagram of a display device capable of recognizing a fingerprint.

Referring to FIG. 1, the display device capable of recognizing a fingerprint includes a cover layer 10, a linear polarization layer 30, a phase delay substrate 50, a plurality of pixels 70, and a photo sensor 90.

The display device illustrated in FIG. 1 may include a display panel and the photo sensor 90. Here, the display panel may include the cover layer 10, the linear polarization layer 30, the phase delay substrate 50, and the plurality of pixels 70.

The display panel may be an OLED panel, but is not limited thereto. The display panel including the cover layer 10, the linear polarization layer 30, the phase delay substrate 50, and the plurality of pixels 70 may correspond to the display panel of the present invention.

The cover layer 10 has a surface which an object such as a finger may contact. The cover layer 10 may have a predetermined thickness and may be made of a transparent material. Further, the cover layer may be made of a flexible material.

The linear polarization layer 30 is disposed below the cover layer 10. The linear polarization layer 30 may be disposed in contact with a lower surface of the cover layer 10, or may be disposed at a predetermined distance from the cover layer 10.

The linear polarization layer 30 passes only linearly polarized light vibrating in a specific direction from input predetermined light.

The phase delay substrate 50 is disposed below the linear polarization layer 30. The phase delay substrate 50 may be disposed to contact the lower surface of the linear polarization layer 30 or may be disposed at a predetermined distance from the linear polarization layer 30.

The phase delay substrate 50 may be a phase delay film or a phase delay layer. For example, the phase delay substrate 50 may be a λ/4 phase delay substrate, and serves to convert linearly polarized light into circularly polarized light, or convert the circularly polarized light into the linearly polarized light.

The phase delay substrate 50 may convert the input linearly polarized light into right-handed circularly polarized light. However, the present invention is not limited thereto, and on the contrary, the phase delay substrate 50 may convert the input linearly polarized light into left-handed circularly polarized light.

Further, when both the right-handed circularly polarized light and the left-handed circularly polarized light are incident on the phase delay substrate 50 together with the linear polarization layer 30, the phase delay substrate 50 may pass only one of both light and block the other. For example, the phase delay substrate 50 may pass the right-handed circularly polarized light and block the left-handed circularly polarized light. The opposite is also possible.

The phase delay substrate 50 may represent a birefringent film formed by stretching a film made of a suitable polymer such as polycarbonate, polyvinyl alcohol, polystyrene or polymethyl methacrylate, polypropylene or other polyolefin, polyacrylate or polyamide or an alignment film of a liquid crystal polymer, a thing in which an alignment layer of the liquid crystal polymer is supported with a film, etc. Further, the phase delay substrate 50 may be made of zeonor resin or Arton.

A reflective surface 60 is a surface positioned between the phase delay substrate 50 and the plurality of pixels 70. The reflective surface 60 may be one surface of one or multiple layers positioned between the phase delay substrate 50 and the plurality of pixels 70. For example, the reflective surface 60 may be one surface of an ITO film, an OCA film, or a PET film disposed between the phase delay substrate 50 and the plurality of pixels 70.

There may be one or more reflective surfaces 60. That is, at least two reflective surfaces 60 may exist between the phase delay substrate 50 and the plurality of pixels 70, and two or more reflective surfaces may be disposed on different planes.

The plurality of pixels 70 are disposed below the phase delay substrate 50 and emit light having a predetermined wavelength. Each pixel 70 may emit light upward or downward.

The light emitted from the plurality of pixels 70 sequentially passes through the phase delay substrate 50, the linear polarization layer 30, and the cover layer 10 and is reflected on a fingerprint F of an object which is in contact with the surface of the cover layer 10 or is close to the surface of the cover layer 10. The light reflected on the fingerprint F may be input into the photo sensor 90 by passing through the cover layer 10, the linear polarization layer 30, and the phase delay substrate 50.

Here, some of the light emitted from the plurality of pixels 70 may be reflected from the reflective surface 60 positioned below the phase delay substrate 50 and input to the photo sensor 90.

The photo sensor 90 is disposed below the reflective surface 60. The photo sensor 90 receives the light emitted from each pixel 70 and reflected on the fingerprint F and the reflective surface 60. The photo sensor 90 includes a plurality of photo sensor pixels having a photoelectric conversion element, and the photoelectric conversion element outputs a predetermined detection signal according to the received light. The output detection signal may be input into a control unit (not illustrated), and the control unit (not illustrated) may detect a pattern of the fingerprint F based on the input detection signal.

Each pixel 70 emits predetermined light. The light emitted from each pixel 70 may have a predetermined wavelength. For example, the pixel 70 may emit green wavelength light, blue wavelength light, and red wavelength light.

The plurality of pixels 70 include a switching thin film transistor (Qs), a driving thin film transistor (Qd), a storage capacitor (Cst), and an organic light emitting diode (OLED) (LD).

The light emitted from each pixel 70 may be unpolarized light. Therefore, the light emitted from each pixel 70 may be expressed as a combination of a right-handed circularly polarized light component (hereinafter, referred to as R component) and a left-handed circularly polarized light component (hereinafter, referred to as L component). The amplitude or intensity of the R component is the same as the amplitude or intensity of the L component.

The photo sensor 90 of the display device illustrated in FIG. 1 receives light R that is reflected on the fingerprint F in contact or close to the surface of the cover layer 10. The photo sensor 90 outputs a predetermined detection signal corresponding to the received light. The output detection signal may be input into a control unit (not illustrated), and the control unit (not illustrated) may detect the pattern of the fingerprint F based on the detection signal.

Here, the light received by the photo sensor 90 of the display device illustrated in FIG. 1 includes light R′ and L′ received while being reflected on the reflective surface 60 disposed between the phase delay substrate 50 and the plurality of pixels 70 as well as the light R received while being reflected on the fingerprint F in contact or close to the surface of the cover layer 10. Here, the light R received while being reflected by the fingerprint F in contact or close to the surface of the cover layer 10 is an optical signal containing fingerprint information required for detection of the fingerprint pattern and the light R′ and L′ received while being reflected on the reflective surface 60 is an ‘internal optical noise signal’ because the light does not include the fingerprint information.

Since the internal optical noise signals R′ and L′ do not contain the fingerprint information, the internal optical noise signals R and L′ are unnecessary signals for detecting the fingerprint pattern. The internal optical noise signals R′ and L′ are one of factors that lower the contrast ratio for the fingerprint pattern.

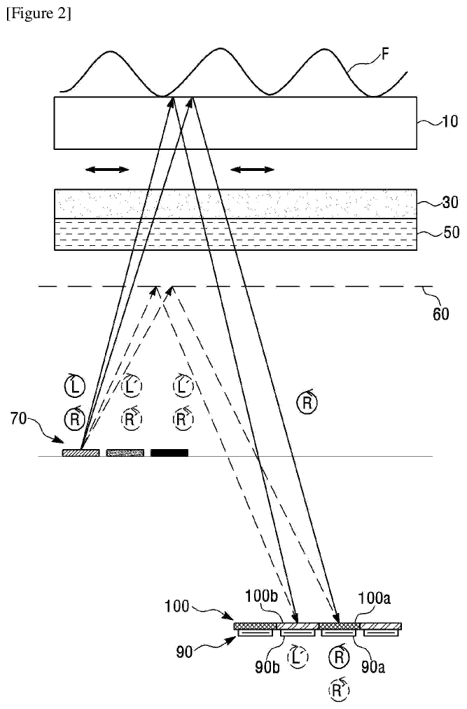

FIG. 2 is a conceptual diagram for describing a display device capable of recognizing a fingerprint according to an embodiment of the present invention.

Referring to FIG. 2, the display device capable of recognizing a fingerprint according to an embodiment of the present invention includes a cover layer 10, a linear polarization layer 30, a phase delay substrate 50, a plurality of pixels 70, a photo sensor 90, and a circular polarizer 100.

The display device capable of recognizing a fingerprint according to embodiment of the present invention illustrated in FIG. 2 further includes the circular polarizer 100 as compared with the display device illustrated in FIG. 1. Accordingly, the cover layer 10, the linear polarization layer 30, the phase delay substrate 50, the plurality of pixels 70, and the photo sensor 90 are replaced with the contents described in FIG. 1.

The circular polarizer 100 is disposed on the photo sensor 90. The circular polarizer 100 may be disposed at a predetermined interval from the top of the photo sensor 90 or disposed in contact with the top of the photo sensor 90. When the circular polarizer 100 and the photo sensor 90 are spaced apart from each other by a predetermined interval, a predetermined optical layer(s) may be disposed between the circular polarizer 100 and the photo sensor 90.

The circular polarizer 100 is disposed below the reflective surface 60. The circular polarizer 100 may receive the internal optical noise signal emitted from each pixel 90 and reflected on the reflective surface 60. Further, the circular polarizer 100 may receive the optical signal emitted from each pixel 90 and reflected on the fingerprint F.

The circular polarizer 100 is disposed between the reflective surface 60 and the photo sensor 90.

The circular polarizer 100 as a sheet type may be attached to a front surface of the photo sensor 90 or a backside of the display panel.

The circular polarizer 100 includes a plurality of circular polarization units 100a and 100b. The number of plurality of circular polarization units 100a and 100b may be equal to the number of a plurality of photo sensor pixels 90a and 90b of the photo sensor 90.

The plurality of circular polarization units 100a and 100b may correspond to the plurality of photo sensor pixels 90a and 90b one to one. That is, one photo sensor pixel may be disposed under one circular polarization unit. However, this is just one example and one circular polarization unit may be disposed on two or more photo sensor pixels according to a design of the circular polarizer 100.

The plurality of circular polarization units 100a and 100b include a first circular polarization unit 100a that passes the right-handed circularly polarized light and blocks the left-handed circularly polarized light and a second circular polarization unit 100b that passes the left-handed circularly polarized light and blocks the right-handed circularly polarized light.

Each of the first circular polarization unit 100a and the second circular polarization unit 100b may be provided as one or multiple units.

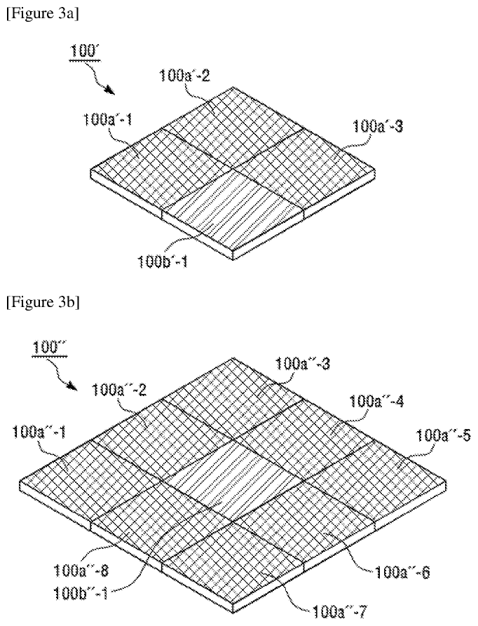

The plurality of first circular polarizing units 100a and the plurality of second circular polarizing units 100b may be alternately disposed. The present invention is not limited thereto and a modified example will be described with reference to FIG. 3.

FIGS. 3(a) and 3(b) are perspective views illustrating a part of a modified example of a circular polarizer 100 illustrated in FIG. 2.

Referring to FIG. 3(a), in a circular polarizer 100′ according to a modified example, the number of first circular polarization units 100a′-1, 100a′-2, and 100a′-3 may be larger than the number of second circular polarization units 100b′-1. More specifically, a ratio of the first circular polarization units 100a′-1, 100a′-2, and 100a′-3 and the second circular polarization unit 100b′-1 may be 3:1.

The plurality of first circular polarization units 100a′-1, 100a′-2, and 100a′-3 may be disposed adjacent to one second circular polarization unit 100b′-1.

The plurality of circular polarizers 100′ illustrated in FIG. 3(a) are regularly arranged to constitute one entire circular polarizer 100′.

Referring to FIG. 3(b), in a circular polarizer 100″ according to a modified example, the number of first circular polarization units 100a″-1, 100a″-2, 100a″-3, 100a″-4, 100a″-5, 100a″-6, 100a″-7, and 100a″-8 may be larger than the number of second circular polarization units 100b″-1. More specifically, a ratio of the first circular polarization units 100a″-1, 100a″-2, 100a″-3, 100a″-4, 100a″-5, 100a″-6, 100a″-7, 100a″-8 and the second circular polarization unit 100b″-1 may be 8:1.

The plurality of first circular polarization units 100a″-1, 100a″-2, 100a″-3, 100a″-4, 100a″-5, 100a″-6, 100a″-7, and 100a″-8 may be disposed adjacent to one second circular polarization unit 100b″-1. For example, the plurality of first circular polarization units 100a″-1, 100a″-2, 100a″-3, 100a″-4, 100a″-5, 100a″-6, 100a″-7, and 100a″-8 may be radially disposed adjacent to a second circular polarization unit 100b″-1 around one second circular polarization unit 100b″-1.

The plurality of circular polarizers 100″ illustrated in FIG. 3(b) are regularly arranged to constitute one entire circular polarizer 100″.

FIGS. 3(a) and 3(b) illustrate that three or eight first circular polarization units are arranged based on one second circular polarization unit, but the present invention is not limited thereto. For example, 4, 5, 6, 7, or 9 or more first circular polarization units may be arranged based on one second circular polarization unit.

Further, in FIGS. 2, 3(a), and 3(b), the first circular polarizing unit and the second circular polarizing unit may be configured in opposite forms. That is, in FIGS. 3(a) and 3(b), the plurality of second circular polarization units may correspond to each other based on the first circular polarization unit.

Referring back to FIG. 2, since the circular polarizer 100 is disposed on the photo sensor 90, the circular polarizer 100 may receive both the internal optical noise signal emitted from each pixel 90 and reflected on the reflective surface 60 and the optical signal reflected on the fingerprint F. Here, since the internal optical noise signal does not pass through the phase delay substrate 50, the internal optical noise signal includes an R component R′ and an L component L′ and since the optical signal reflected on the fingerprint F passes through the phase delay substrate 50, the optical signal includes only the R component R.

In this case, since the first circular polarization unit 100a of the circular polarizer 100 passes a right-handed circularly polarized wave and blocks a left-handed circularly polarized wave, the first circular polarization unit 100a passes the R component R′ of the internal optical noise signal and the R component R of the optical signal and blocks the L component L′ of the internal optical noise signal. Accordingly, the first photo sensor pixel 90a positioned below the first circular polarization unit 100a receives the R component R′ of the internal optical noise signal and the R component R of the optical signal.

Meanwhile, since the second circular polarization unit 100a of the circular polarizer 100 passes the left-handed circularly polarized wave and blocks the right-handed circularly polarized wave, the second circular polarization unit 100b blocks the R component R′ of the internal optical noise signal and the R component R of the optical signal and passes the L component L′ of the internal optical noise signal. Accordingly, the second photo sensor pixel 90b positioned below the second circular polarization unit 100b receives the L component L′ of the internal optical noise signal.

By the circular polarizer 100, the internal optical noise signal input into the photo sensor 90 is reduced as compared with the case of FIG. 1. In other words, each photo sensor pixel of the photo sensor 90 illustrated in FIG. 1 receives the R component R′ and the L component L′ of the internal optical noise signal and the R component R of the optical signal together, but the R component R of the optical signal and the R component R of the internal optical noise signal are received by the first photo sensor pixel 90a of the photo detector 100 illustrated in FIG. 2 and the L component L′ of the internal optical noise signal is received by the second photo sensor pixel 90b.

The first photo sensor pixel 90a of the photo sensor 90 outputs a predetermined first detection signal based on the R component R′ of the received internal optical noise signal and the R component R of the optical signal and the second photo sensor pixel 90b outputs a predetermined second detection signal based on the L component L′ of the received internal optical noise signal. The output first detection signal and second detection signal are input to a control unit (not illustrated).

The control unit (not illustrated) detects the fingerprint pattern based on the input first and second detection signals. For example, the control unit (not illustrated) may detect the fingerprint pattern by subtracting the second detection signal from the first detection signal. In this case, since the amplitudes or intensities of the R component R of the internal optical noise signal and the L component L′ of the internal optical noise signal are the same, the fingerprint pattern may be detected by the R component R of the optical signal containing the fingerprint information. Accordingly, the display device capable of recognizing a fingerprint according to an embodiment of the present invention illustrated in FIG. 2 may exclude the internal optical noise signal when detecting the fingerprint pattern, thereby enhancing the contrast ratio and acquiring the accurate fingerprint pattern.

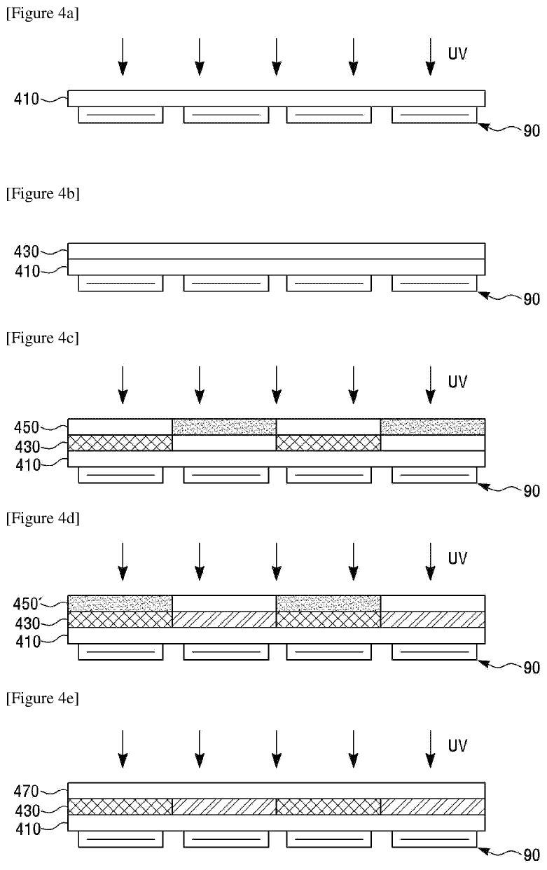

FIGS. 4(a) to 4(e) are diagrams for describing a method for manufacturing a circular polarizer 100 illustrated in FIG. 2.

Referring to FIG. 4(a), a polarization layer 410 is formed on the photo sensor 90. A material forming the polarization layer 410 is coated on the photo sensor 90 and UV light having a polarized state in any one direction (first direction) is applied to the material. Then, the polarization layer 410 may be formed as material molecules of the polarization layer 410 elongate in the any one direction.

Referring to FIG. 4(b), a polymer layer 430 is formed on the polarization layer 410. The polymer layer 430 may be a light polymerizable polymer. Here, the formed polymer layer 430 may have a smaller thickness than the polarization layer 410.

Referring to FIG. 4(c), a first mask layer 450 is formed on the polymer layer 450, and the UV light having a polarized state in a direction by an angle of +45 degrees from the polarization direction of the polarization layer 410 is applied to the first mask layer 450. Then, regions which pass the right-handed circularly polarized wave are formed in the polymer layer 450.

Referring to FIG. 4(d), a second mask layer 450′ is formed on the polymer layer 450, and the UV light having a polarized state in a direction by an angle of −45 degrees from the polarization direction of the polarization layer 410 is applied to the second mask layer 450′. Then, regions which pass the left-handed circularly polarized wave are formed in the polymer layer 450.

Referring to FIG. 4(e), a liquid crystal polymer layer 450 is formed on the polymer layer 450 on which regions passing the right-handed circularly polarized wave and regions passing the left-handed circularly polarized wave are formed. Then, the liquid crystal polymer layer 450 is cured. For example, when predetermined UV light is applied onto the liquid crystal polymer layer 450, liquid crystals of the liquid crystal polymer layer 450 are arranged in the same direction as the polarization direction of the polymer layer 450 formed therebelow.

According to a manufacturing method of the circular polarizer 100 illustrated in FIGS. 4(a) to 4(e), a thin circular polarizer 100 having a thickness of approximately 5 to 6 um may be acquired.

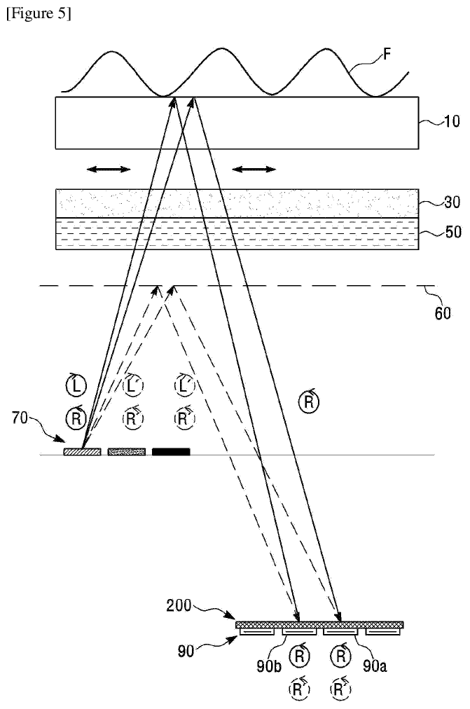

FIG. 5 is a conceptual diagram for describing a display device capable of recognizing a fingerprint according to another embodiment of the present invention.

Referring to FIG. 5, the display device capable of recognizing a fingerprint according to another embodiment of the present invention includes a cover layer 10, a linear polarization layer 30, a phase delay substrate 50, a plurality of pixels 70, a photo sensor 90, and a circular polarizer 200.

The display device capable of recognizing a fingerprint according to another embodiment of the present invention illustrated in FIG. 5 further includes the circular polarizer 200 as compared with the display device illustrated in FIG. 1. Accordingly, the cover layer 10, the linear polarization layer 30, the phase delay substrate 50, the plurality of pixels 70, and the photo sensor 90 are replaced with the contents described in FIG. 1.

The circular polarizer 200 illustrated in FIG. 5 is different from the circular polarizer 100 illustrated in FIG. 2. The circular polarizer 100 illustrated in FIG. 2 includes the first circular polarization unit 100a passing one of the right-handed circularly polarized wave and the left-handed circularly polarized wave and the second circular polarization unit 100b passing the other, but the circular polarizer 200 illustrated in FIG. 5 passes only any one of the right-handed circularly polarized wave and the left-handed circularly polarized wave.

The circular polarizer 200 illustrated in FIG. 5 is disposed on the photo sensor 90. Further, the circular polarizer 200 may be disposed between the reflective surface 60 and the photo sensor 90. The circular polarizer 200 may be disposed at the same location as the circular polarizer 100 illustrated in FIG. 2.

The circular polarizer 200 passes the right-handed circularly polarized wave and blocks the left-handed circularly polarized wave. Here, in FIG. 5, it is illustrated that the circular polarizer 200 passes the right-handed circularly polarized wave, but the present invention is not limited thereto and the circular polarizer 200 may pass the left-handed circularly polarized wave. In this case, alternatively, the phase delay substrate 50 should pass the left-handed circularly polarized wave and block the right-handed circularly polarized wave. That is, the circular polarizer 200 and the phase delay substrate 50 illustrated in FIG. 5 pass through the same one of the left-handed circularly polarized wave and the right-handed circularly polarized wave.

The circular polarizer 200 may be disposed on the plurality of photo sensor pixels 90a and 90b of the photo sensor 90.

In the display device capable of recognizing a fingerprint according to another embodiment of the present invention illustrate in FIG. 5, since the circular polarizer 200 blocks the L component L′ of the internal optical noise signal reflected on the reflective surface 60 and input, the R component R of the internal optical noise signal and the R component R of the optical signal are received by each of the photo sensor pixels 90a and 90b.

In the display device capable of recognizing a fingerprint according to another embodiment of the present invention illustrated in FIG. 5, since the photo sensor 90 receives the R component R′ of one internal optical noise signal per R component R of one optical signal, the intensity of the internal optical noise signal is reduced by ½ by the circular polarizer 200, as compared with the display device illustrated in FIG. 2.

Meanwhile, the circular polarizer 200 illustrated in FIG. 5 may be manufactured by a simpler method than the manufacturing method of the circular polarizer 100 illustrated in FIGS. 4(a) to 4(e). Specifically, FIGS. 4(a) and 4(b) are performed as they are, but in FIG. 4(c), UV light having a polarized state in a direction different from the polarization direction of the polarization layer 410 by an angle of +45 degrees without the first mask layer 450 is applied, FIG. 4(d) is omitted and FIG. 4(e) is performed as it is, and as a result, the circular polarizer 200 illustrated in FIG. 5 may be manufactured.

Here, in changing FIG. 4(c), UV light having a polarized state in a direction different from the polarization direction of the polarization layer 410 by an angle of −45 degrees may be applied. In this case, the circular polarizer passing the left-handed circularly polarized light may be manufactured.

The circular polarizer 200 illustrated in FIG. 5 as the sheet type may be thicker than the circular polarizer 100 manufactured by FIGS. 4(a) to 4(e), but the manufacturing method is simpler.

Accordingly, since the circular polarizer 200 illustrated in FIG. 5 is the sheet type, the circular polarizer 200 may be attached to the backside of the display panel in addition to the photo sensor 90. Here, the display panel may be the OLED panel.

The features, structures, and effects described in each of the above-described embodiments are included in an embodiment of the present invention, but are not particularly limited to the embodiment. Furthermore, the features, structures, and effects illustrated in each embodiment will be able to be combined, modified, changed, converted, substituted, added, modified, transformed, and applied by those skilled in the art in the technical field to which the present invention belongs. Accordingly, combinations, modifications, changes, conversions, substitutions, additions, and modifications may also be construed as being included in the scope of the present invention without departing from the technical spirit described in the appended claims.

### EXPLANATION OF REFERENCE NUMERALS AND SYMBOLS

10: Cover layer

30: Linear polarization layer

50: Phase delay substrate

70: Pixel

90: Photo sensor

100, 200: Circular polarizer

1. A display device capable of recognizing a fingerprint, the display device comprising:
a cover layer;
a linear polarization layer disposed below the cover layer;
a phase delay substrate disposed below the linear polarization layer;
a plurality of pixels disposed below the phase delay substrate and emitting predetermined light;
a reflective surface disposed between the phase delay substrate and the plurality of pixels;
a photo sensor disposed below the reflective surface, having a plurality of photo sensor pixels, and receiving an optical signal from a fingerprint which is in contact with or is close to the cover layer and an internal optical noise signal from the reflective surface; and
a circular polarizer disposed between the reflective surface and the photo sensor, and including a first circular polarization unit passing right-handed circularly polarized light and blocking left-handed circularly polarized light and a second circular polarization unit blocking the right-handed circularly polarized light and passing the left-handed circularly polarized light.

2. The display device capable of recognizing a fingerprint of claim 1, wherein there are a plurality of first circular polarization units and a plurality of second circular polarization units, and
the plurality of first circular polarization units and the plurality of second circular polarization units correspond to the plurality of photo sensor pixels one to one, and
the plurality of first circular polarization units and the plurality of second circular polarization units are alternately disposed.

3. The display device capable of recognizing a fingerprint of claim 1, wherein the phase delay substrate converts the light emitted from each pixel into the right-handed circularly polarized light, and
the first circular polarization unit passes the right-handed circularly polarized light of the optical signal and the internal optical noise signal and blocks the left-handed circularly polarized light of the internal optical noise signal, and
the second circular polarization unit blocks the right-handed circularly polarized light of the optical signal and the internal optical noise signal and passes the left-handed circularly polarized light of the internal optical noise signal.

4. The display device capable of recognizing a fingerprint of claim 1, wherein the phase delay substrate converts the light emitted from each pixel into the left-handed circularly polarized light, and
the first circular polarization unit passes the right-handed circularly polarized light of the internal optical noise signal and blocks the left-handed circularly polarized light of the optical signal and the internal optical noise signal, and
the second circular polarization unit blocks the right-handed circularly polarized light of the internal optical noise signal and passes the left-handed circularly polarized light of the optical signal and the internal optical noise signal.

5. The display device capable of recognizing a fingerprint of claim 1, wherein there are a plurality of first circular polarization units and a plurality of second circular polarization units, and
the number of plurality of first circular polarization units is different from the number of plurality of second circular polarization units.

6. The display device capable of recognizing a fingerprint of claim 5, wherein two or more remaining polarization units are disposed adjacent to any one polarization unit of the first circular polarization unit and the second circular polarization unit.

7. The display device capable of recognizing a fingerprint of claim 5, wherein a plurality of remaining polarization units are radially disposed adjacent to any one polarization unit of the first circular polarization unit and the second circular polarization unit.

8. A display device capable of recognizing a fingerprint, the display device comprising:
a cover layer;
a linear polarization layer disposed below the cover layer;
a phase delay substrate disposed below the linear polarization layer;
a plurality of pixels disposed below the phase delay substrate and emitting predetermined light;
a reflective surface disposed between the phase delay substrate and the plurality of pixels;
a photo sensor disposed below the reflective surface, having a plurality of photo sensor pixels, and receiving an optical signal from a fingerprint which is in contact with or is close to the cover layer and an internal optical noise signal from the reflective surface; and
a circular polarizer disposed between the reflective surface and the photo sensor, and including a circular polarization unit passing any one of right-handed circularly polarized light and left-handed circularly polarized light and blocking the other.

9. The display device capable of recognizing a fingerprint of claim 8, wherein the phase delay substrate converts the light emitted from each pixel into the right-handed circularly polarized light, and
the circular polarizer passes the right-handed circularly polarized light and blocks left-handed circularly polarized light.

10. The display device capable of recognizing a fingerprint of claim 8, wherein the phase delay substrate converts the light emitted from each pixel into the left-handed circularly polarized light, and
the circular polarizer passes the left-handed circularly polarized light and blocks right-handed circularly polarized light.

11. The display device capable of recognizing a fingerprint of claim 8, wherein the circular polarization layer is a sheet type, and
the circular polarization layer is attached to a backside of a display panel including the cover layer, the linear polarization layer, the phase delay substrate, the reflective surface, the plurality of pixels or the photo sensor.

12. The display device capable of recognizing a fingerprint of claim 8, further comprising:
a control unit detecting a fingerprint pattern of the fingerprint based on a detection signal output from each photo sensor pixel of the photo sensor.

13. The display device capable of recognizing a fingerprint of claim 1, wherein the circular polarization layer is a sheet type, and
the circular polarization layer is attached to a backside of a display panel including the cover layer, the linear polarization layer, the phase delay substrate, the reflective surface, the plurality of pixels or the photo sensor.

14. The display device capable of recognizing a fingerprint of claim 1, further comprising:
a control unit detecting a fingerprint pattern of the fingerprint based on a detection signal output from each photo sensor pixel of the photo sensor.
